(19) United States
(12) Patent Application Publication
(10) Pub. No.: US 2022/0284148 A1
(43) Pub. Date: Sep. 8, 2022

(54) SYSTEM AND METHOD OF MANAGING A DESIGN LIFECYCLE OF A STRUCTURAL PART

(71) Applicant: The Boeing Company, Chicago, IL (US)

(72) Inventors: Eric S. Lester, Edmonds, WA (US); Samir Abad, Bellevue, WA (US); George Bojko, Snohomish, WA (US); Abul Azad, Woodinville, WA (US); Venkata Narasimha Ravi Udali, Bothell, WA (US); Vivek Mohan, Everett, WA (US)

(21) Appl. No.: 17/665,097

(22) Filed: Feb. 4, 2022

Related U.S. Application Data
(60) Provisional application No. 63/157,131, filed on Mar. 5, 2021.

(51) Int. Cl. G06F 30/15; G06Q 30/06

(52) U.S. Cl. CPC G06F 30/15; G06Q 30/0625

(57) ABSTRACT

A method of managing a design lifecycle of a structural part includes accessing memory storing computer-readable program code for identifying a supplier for the structural part. The method includes executing the code to cause an apparatus to identify the supplier. The method also includes generating a first design of the structural part, the first design describing a geometry of the structural part and requirements for attributes of the structural part. The method also includes performing a search of a database of existing designs for a second design based on search criteria including multiple ones of the geometry and the requirements, and selecting a design from the first design and the second design based on the search. The method also includes performing a multiple-criteria decision analysis to evaluate the design, identifying the supplier from multiple suppliers, and outputting an indication of the supplier for use in ordering of the structural part.

### CROSS-REFERENCE TO RELATED APPLICATION(S)

This application claims priority of U.S. Provisional Patent Application No. 63/157,131, filed on Mar. 5, 2021, entitled System and Method of Managing a Design Lifecycle of a Structural Part, the content of which is incorporated herein in its entirety by reference.

### TECHNOLOGICAL FIELD

The present disclosure relates generally to the design of structural parts and, in particular, to managing a design lifecycle of a structural part.

### BACKGROUND

Conventional engineering processes for development of structural parts involve specification control drawings (SCD) provided to suppliers. Suppliers then perform design, analysis, testing and manufacturing. These engineering processes pose challenges to search and identify existing part numbers for various design and/or manufacturing attributes. Redundant parts often exist with different part numbers that need to be streamlined and standardized. Problems may also be encountered with a lack of traceability of end-to-end integration of design and analysis data all the way through supply chain, which may result in cost overruns. Conventional processes are mostly document based, which may be challenging to search and trace relevant data. A need exists for a model-based engineering process to enable cost reduction, design standardization, and design reuse.

Therefore, it would be desirable to have a system and method that takes into account at least some of the issues discussed above, as well as other possible issues.

### BRIEF SUMMARY

Example implementations of the present disclosure are directed to the design of structural parts and, in particular, to managing a design lifecycle of a structural part. In accordance with example implementations, multiple processes may be integrated into an automated process. The integration may thus eliminate redundancy and enable design standardization of structural parts from suppliers by using designs as will be further disclosed.

Managing a model based engineering (MBE) lifecycle digital thread process may optimize and reduce cost from design of the structural part to supply chain integration by relating known data in a manner to create a useful output. The existing designs of a structural part may be combined with machine learning techniques that may utilize the attributes of the structural part. and produce outputs to aid in reducing cost in design, manufacturing, and supply management.

The present disclosure thus includes, without limitation, the following example implementations.

Some example implementations provide a method of managing a design lifecycle of a structural part, the method comprising: accessing memory storing computer-readable program code for identifying a supplier for the structural part; and executing the computer-readable program code, via processing circuitry, to cause an apparatus to identify the supplier, including the apparatus at least: generating a first design of the structural part, the first design describing a geometry of the structural part and requirements for attributes of the structural part including a rated capability, weight, and cost; performing a search of a manufacturing database of existing designs for a second design of the structural part based on search criteria including multiple ones of the geometry and the requirements; selecting a design from the first design and the second design based on the search, the second design selected when the second design matches the search criteria, and the first design selected when none of the existing designs match the search criteria; performing a multiple-criteria decision analysis to evaluate the design based on multiple selection criteria including the attributes of different units of the structural part as manufactured by multiple suppliers according to the design; identifying the supplier from the multiple suppliers based on the multiple-criteria decision analysis; and outputting an indication of the supplier for use in ordering of the structural part from the supplier.

In some example implementations of the method of any preceding example implementation, or any combination of any preceding example implementations, multiple second designs match the search criteria, and selecting the design includes determining an order of priority of the multiple second designs, and selecting the design from the multiple second designs according to the order of priority.

In some example implementations of the method of any preceding example implementation, or any combination of any preceding example implementations, the structural part is a vehicle part, selecting the design includes selecting the second design, and performing the multiple-criteria decision analysis includes analyzing historical data for the second design, including usage of the vehicle part as manufactured according to the second design, and across multiple vehicles.

In some example implementations of the method of any preceding example implementation, or any combination of any preceding example implementations, performing the multiple-criteria decision analysis includes performing data clustering in which the historical data is clustered by the multiple selection criteria based on parameters including one or more of a fixed number of clusters, a distance between a data point at a center of a cluster and other data points in the cluster, or a minimum number of data points in a cluster.

In some example implementations of the method of any preceding example implementation, or any combination of any preceding example implementations, wherein the structural part is a vehicle part, selecting the design includes selecting the second design, and the apparatus caused to identify the supplier further includes the apparatus at least: determining demand and supply trends for the structural part as manufactured according to the second design, based on historical data for the second design; and outputting a display of information including a demand and supply curve based on the demand and supply trends, the demand and supply curve informing at least one of a predicted demand or shortage in supply of the structural part.

In some example implementations of the method of any preceding example implementation, or any combination of any preceding example implementations, outputting the display of information includes outputting the display of information further including costs and quantities of the structural part from respective ones of the multiple suppliers.

In some example implementations of the method of any preceding example implementation, or any combination of any preceding example implementations, generating the first design comprises: generating a three-dimensional (3D) model of the structural part based on the geometry and the requirements; determining whether the 3D model meets safety requirements; and when the 3D model meets the safety requirements, determining a cost of the structural part based on the 3D model; and generating the first design based on at least the 3D model and the cost.

In some example implementations of the method of any preceding example implementation, or any combination of any preceding example implementations, the structural part has geometric features including one or more tapers or holes, and generating the first design further comprises generating two-dimensional (2D) renderings of the structural part from the 3D model, and based on dimensions of the geometric features.

In some example implementations of the method of any preceding example implementation, or any combination of any preceding example implementations, determining whether the 3D model meets safety requirements comprises determining whether the 3D model meets safety requirements for tension, compression, and thread shear.

In some example implementations of the method of any preceding example implementation, or any combination of any preceding example implementations, when the 3D model does not meet the safety requirements, the method further comprises: modifying one or more of the geometry or requirements of the structural part to meet the safety requirements; and regenerating the 3D model based on the geometry and the requirements as modified.

Some example implementations provide an apparatus for managing a design lifecycle of a structural part, the apparatus comprising memory configured to store computer-readable program code for identifying a supplier for the structural part; and processing circuitry configured to access the memory and execute the computer-readable program code to cause the apparatus to at least perform the method of any preceding example implementation, or any combination of any preceding example implementations.

Some example implementations provide a computer-readable storage medium for managing a design of a lifecycle part, the computer-readable storage medium being non-transitory and having computer-readable program code stored therein that, in response to execution by processing circuitry, causes an apparatus to at least perform the method of any preceding example implementation, or any combination of any preceding example implementations.

These and other features, aspects, and advantages of the present disclosure will be apparent from a reading of the following detailed description together with the accompanying figures, which are briefly described below. The present disclosure includes any combination of two, three, four or more features or elements set forth in this disclosure, regardless of whether such features or elements are expressly combined or otherwise recited in a specific example implementation described herein. This disclosure is intended to be read holistically such that any separable features or elements of the disclosure, in any of its aspects and example implementations, should be viewed as combinable unless the context of the disclosure clearly dictates otherwise.

It will therefore be appreciated that this Brief Summary is provided merely for purposes of summarizing some example implementations so as to provide a basic understanding of some aspects of the disclosure. Accordingly, it will be appreciated that the above described example implementations are merely examples and should not be construed to narrow the scope or spirit of the disclosure in any way. Other example implementations, aspects and advantages will become apparent from the following detailed description taken in conjunction with the accompanying figures which illustrate, by way of example, the principles of some described example implementations.

### BRIEF DESCRIPTION OF THE FIGURE(S)

Having thus described example implementations of the disclosure in general terms, reference will now be made to the accompanying figures, which are not necessarily drawn to scale, and wherein:

FIG. 1 illustrates a system for managing a design lifecycle of a structural part, according to example implementations of the present disclosure;

FIGS. 2A and 2B illustrate an example algorithm of a design module and a user interface associated therewith, according to example implementations;

FIG. 3 illustrates an example algorithm of an analysis module, according to example implementations;

FIG. 4 illustrates an example algorithm for am manufacturing module, according to example implementations;

FIG. 5 illustrates an example of a data clustering algorithm, according to example implementations;

FIG. 6 illustrates an example of a multilayer perceptron (MLP) as an artificial neural network (ANN), according to example implementations;

FIGS. 7A, 7B, 7C, 7D, and 7E illustrates example outputs representing data regarding a supplier and a design of a structural part, according to example implementations;

FIG. 8 illustrates another example of an MLP as an ANN, according to example implementations;

FIGS. 9A, 9B, 9C, 9D, and 9E illustrate example outputs representing forecasting data, according to example implementations;

FIGS. 10A, 10B, 10C, 10D, 10E, 10F, 10G, and 10H are flowcharts illustrating various steps in a method of managing a design lifecycle of a structural part of a structural part, according to example implementations; and

FIG. 11 illustrates an apparatus according to some example implementations.

### DETAILED DESCRIPTION

Some implementations of the present disclosure will now be described more fully hereinafter with reference to the accompanying figures, in which some, but not all implementations of the disclosure are shown. Indeed, various implementations of the disclosure may be embodied in many different forms and should not be construed as limited to the implementations set forth herein; rather, these example implementations are provided so that this disclosure will be thorough and complete, and will fully convey the scope of the disclosure to those skilled in the art. Like reference numerals refer to like elements throughout.

Unless specified otherwise or clear from context, references to first, second or the like should not be construed to imply a particular order. A feature described as being above another feature (unless specified otherwise or clear from context) may instead be below, and vice versa; and similarly, features described as being to the left of another feature else may instead be to the right, and vice versa. Also, while reference may be made herein to quantitative measures, values, geometric relationships or the like, unless otherwise stated, any one or more if not all of these may be absolute or approximate to account for acceptable variations that may occur, such as those due to engineering tolerances or the like.

As used herein, unless specified otherwise or clear from context, the “or” of a set of operands is the “inclusive or” and thereby true if and only if one or more of the operands is true, as opposed to the “exclusive or” which is false when all of the operands are true. Thus, for example, “[A] or [B]” is true if [A] is true, or if [B] is true, or if both [A] and [B] are true. Further, the articles “a” and “an” mean “one or more,” unless specified otherwise or clear from context to be directed to a singular form. Furthermore, it should be understood that unless otherwise specified, the terms “data,” “content,” “digital content,” “information,” and similar terms may be at times used interchangeably.

Example implementations of the present disclosure are directed to design of structural parts and, in particular, to managing a design lifecycle of a structural part. The feature described herein may be beneficial for reducing or eliminating redundancies of structural parts from suppliers, thereby reducing costs related to material procurement and manufacturing, as well as reducing time delays associated with finding and determining a design for a structural part by conventional means.

A model-based engineering (MBE) process may provide a digital thread solution with primary goal of moving away from specification control drawings (SCDs) to build-to-print (BTP). A proposed digital thread solution may capture end-to-end lifecycle data for structural parts such as design, analysis, test and cost information. The data is subsequently stored in a database which enables searching and reuse of engineering data. A proposed MBE solution may include a design search algorithm that may enable single or combinational search based on various shapes, sizes, load carrying capabilities, part numbers, weight and cost information. A design reuse algorithm may also be included that may create multiple data clusters based on geometry configuration, supplier IDs, and cost to weight ratios. The data clusters in turn may help to enable design reuse based on various criteria, and the proposed solution may provide design space visibility of structural parts and enable reuse of existing. The MBE solution may also include predictive digital thread analytics utilizing artificial Intelligence (AI) based machine learning solutions to perform data analytics on historical lifecycle data (e.g., design, analysis, weight, cost, supplier ID), and may establish a relationship between various data parameters. The solution may subsequently test and train the data and predict the cost effective structural part and supplier IDs.

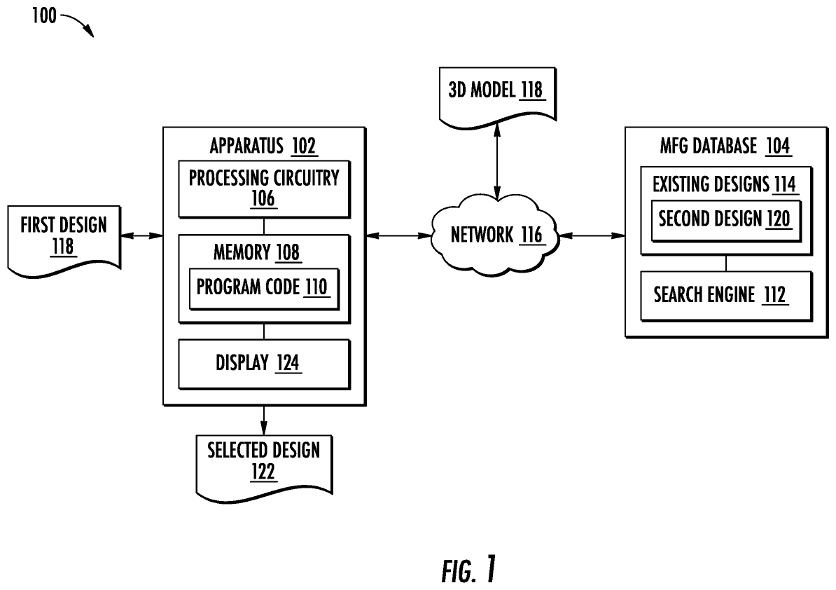

FIG. 1 illustrates a system 100 for managing a design lifecycle of a structural part, according to example implementations of the present disclosure. The structural part may be a tierod, bushing, or any other part as may be appropriate for design lifecycle management. Though examples provided may describe structural parts that are vehicle parts, it should be understood that other non-vehicle parts may also be utilized. The system may include any of a number of different subsystems (each an individual system) for performing one or more functions or operations. As shown, in some examples, the system includes an apparatus 102 and a manufacturing (MFG) database 104.

As also shown, the apparatus 102 includes processing circuitry 106, and memory 108 storing computer-readable program code 110 for identifying a supplier for a structural part. The manufacturing database includes a search engine 112 and existing designs 114. The subsystems including the apparatus and manufacturing database may be co-located or directly coupled to one another, or in some examples, various ones of the subsystems may communicate with one another across one or more computer networks 116. Further, although shown as part of the system, it should be understood that any one or more of the above may function or operate as a separate system without regard to any of the other subsystems. It should also be understood that the system may include one or more additional or alternative subsystems than those shown in FIG. 1.

According to example implementations of the present disclosure, the processing circuitry 106 of the apparatus 102 is configured to access the memory 108 and execute the computer-readable program code 110 to cause the apparatus to identify the supplier. In this regard, the apparatus is caused to at least generate a first design 118 of the structural part, the first design describing a geometry of the structural part and requirements for attributes of the structural part including a rated capability (e.g., a load carrying capability), weight, and cost. The apparatus may also be caused to perform a search of the manufacturing database 104 of existing designs 114 for a second design 120 of the structural part based on search criteria including multiple ones of the geometry and the requirements.

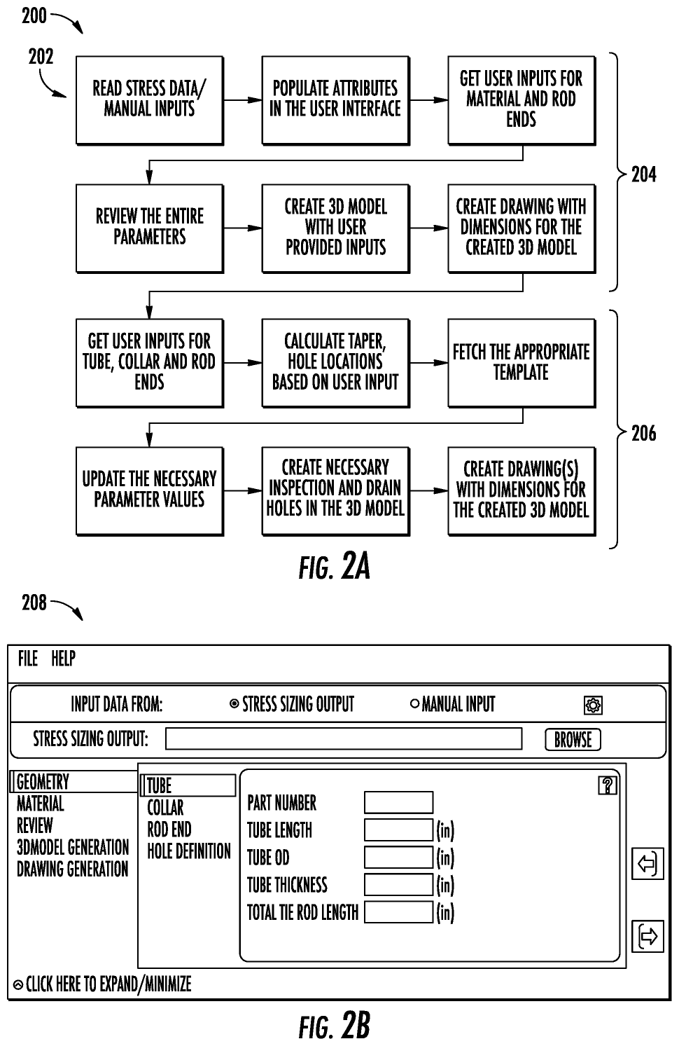

In some examples, generating the first design 118 may be characterized as including a plurality of modules. A requirement/functional/logical/physical (RFLP) model with initial data may be input into various MBE modules including a design module, an analysis module, and/or a manufacturing module. As shown in FIG. 2A, the design module 200 may include an algorithm 202 to generate the first design 118 based on receiving inputs such as the RFLP model and may also take in user inputs. As shown in algorithm section 204, according to some examples, algorithm 202 uses various inputs to create the 3D model. In these examples, the algorithm continues in algorithm section 206 to generate two-dimensional (2D) renderings (drawings) from the 3D model. FIG. 2B illustrates an example of a user interface 208 that may be suitable for entering the user inputs.

In some examples, the apparatus 102 is further caused to select a design 122 from the first design 118 and the second design 120 based on the search. The second design is selected when the second design matches the search criteria, and the first design is selected when none of the existing designs match the search criteria. A multiple-criteria decision analysis may be performed to evaluate the design based on multiple selection criteria including the attributes (e.g., the rated capability, weight, cost) of different units of the structural part as manufactured by multiple suppliers according to the design. In some examples, when multiple second designs 120 match the search criteria, the apparatus 102 is caused to determine an order of priority of the multiple second designs, and select the design from the multiple second designs according to the order of priority.

In some examples, the apparatus 102 is further caused to identify the supplier from the multiple suppliers based on the multiple-criteria decision analysis, and output an indication of the supplier for use in ordering of the structural part from the supplier.

In some examples in which the second design 120 is selected for a vehicle part, the multiple-criteria decision analysis includes the apparatus 102 caused to analyze historical data for the second design, including usage of the vehicle part as manufactured according to the second design, and across multiple vehicles. In other examples in which the second design 120 is selected for a vehicle part, the apparatus caused to identify the supplier further includes the apparatus caused to at least determine demand and supply trends for the structural part as manufactured according to the second design. The determined demand and supply trends may be based on historical data for the second design.

The apparatus 102 may be further caused to output a display 124 of information including a demand and supply curve based on the demand and supply trends, the demand and supply curve informing at least one of a predicted demand or shortage in supply of the structural part. The display of information may include costs and quantities of the structural part from respective ones of the multiple suppliers.

In some examples, the multiple-criteria decision analysis includes the apparatus 102 caused to perform data clustering in which the historical data is clustered by the multiple selection criteria based on various parameters. The parameters may include one or more of a fixed number of clusters, a distance between a data point at a center of a cluster and other data points in the cluster, or a minimum number of data points in a cluster.

In some examples, generation of the first design 118 includes the apparatus 102 caused to generate the first design of a three-dimensional (3D) model of the structural part based on the geometry and the requirements, and determine whether the 3D model meets safety requirements. When the 3D model meets the safety requirements, the apparatus may be caused to determine a cost of the structural part based on the 3D model and generate the first design based on at least the 3D model and the cost. In some of these examples, the structural part has geometric features including one or more tapers or holes, and the apparatus caused to generate the first design also includes the apparatus caused to generate the (2D) renderings of the structural part from the 3D model, and based on dimensions of the geometric features.

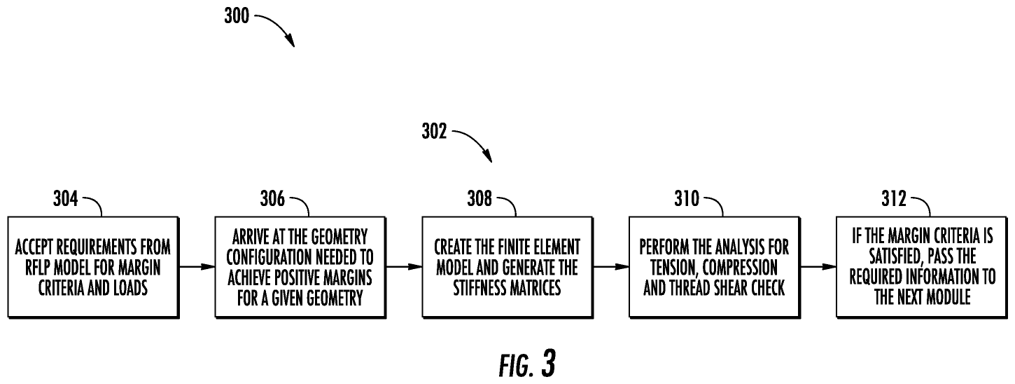

FIG. 3 shows an example of an analysis module 300 including an algorithm 302 to determine if safety requirements (which may also be referred to as margin criteria) are met for the 3D model, which may include analysis of the load carrying capability and determination of the necessary geometry configuration, as shown at blocks 304 and 306. In some of these examples, a finite element model is generated and analysis of the load carrying capability includes analyzing tension, compression, and thread shear, as shown at blocks 308 and 310. When the safety requirements are met, the analysis module may proceed to pass the information to the next module for determining a cost of the structural part, as shown at block 312. In examples where the 3D model does not meet the safety requirements, the apparatus may be further caused to modify one or more of the geometry or requirements of the structural part to meet the safety requirements and regenerate the 3D model based on the geometry and the requirements as modified.

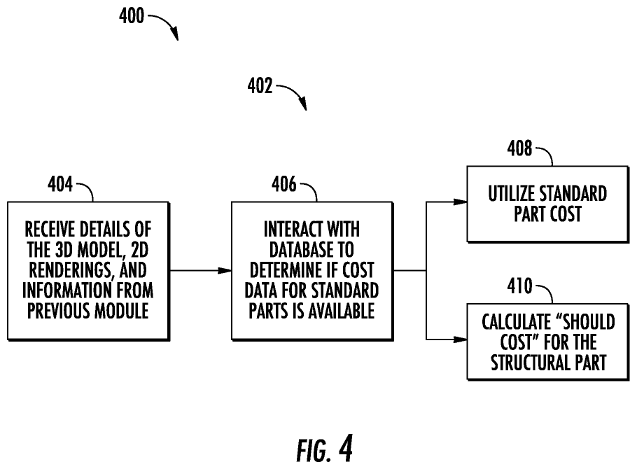

FIG. 4 illustrates an example of a manufacturing module 400 including an algorithm 402, to predict the manufacturing cost of the structural part according to a determination of whether the standard part cost data is available from a database for standard parts. The manufacturing module is configured to receive the information from the previous module 300, as shown at block 404, and interacts with a database to determine if cost data for standard parts is available, as shown at block 406. Based on the determination of availability, the algorithm proceeds to either utilize the standard part cost data or calculate a “should cost” for the structural part, as shown respectively at blocks 408 and 410.

Returning to the multiple-decision criteria analysis, this may be characterized in some examples as including the implementation of artificial intelligence (AI) and machine learning (ML). The implementation of ML may include data collection 500 and data clustering 502, as shown in FIG. 5. The data collection may include loading data from the manufacturing database 104 by querying all relevant input parameters; rescaling the data; and removing redundancies from the data. The results of the data collection process may be passed to the data clustering algorithm 502. Data clustering may involve using k-means (i.e., a k-means algorithm) to group similar data together to discover underlying patterns. The k-means algorithm may utilize a fixed number of clusters (k), as shown at block 504, in which each cluster is a group of data points aggregated together based on determined similarities. The k number of clusters may be set based on the number of centroids in the data set, a centroid being a location representing the center of a cluster, as shown at block 506. The k-means algorithm may identify the centroids for the k number of clusters and allocate each data point to the nearest cluster, as shown at block 508, while keeping the distance from each data point to its centroid as small as possible, as shown at block 510. In this manner, each data point is associated with the centroid to which the distance therebetween is the smallest. As shown at block 512, the data clustering 502 repeats for each new cluster.

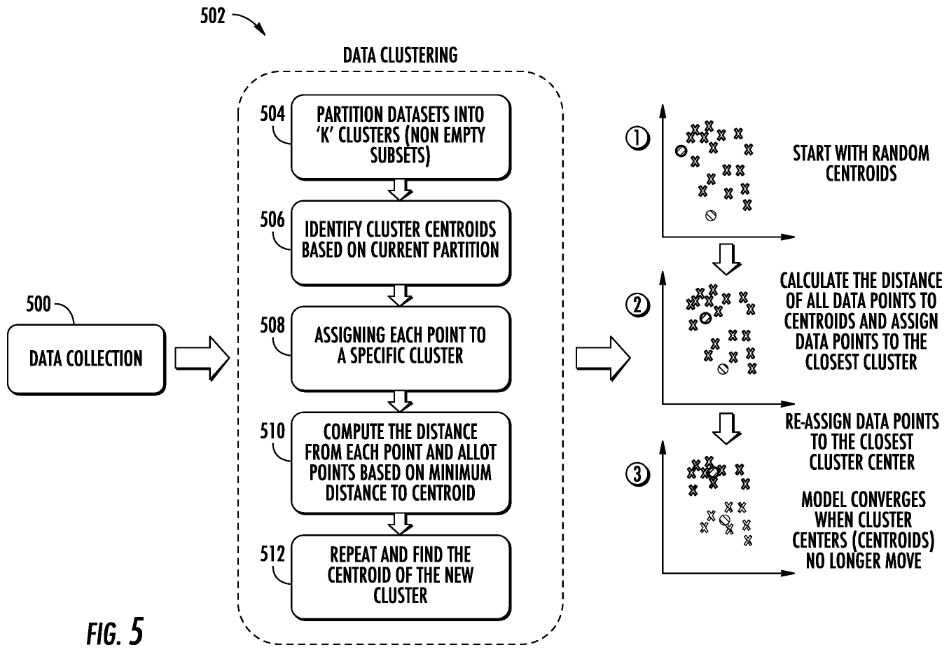

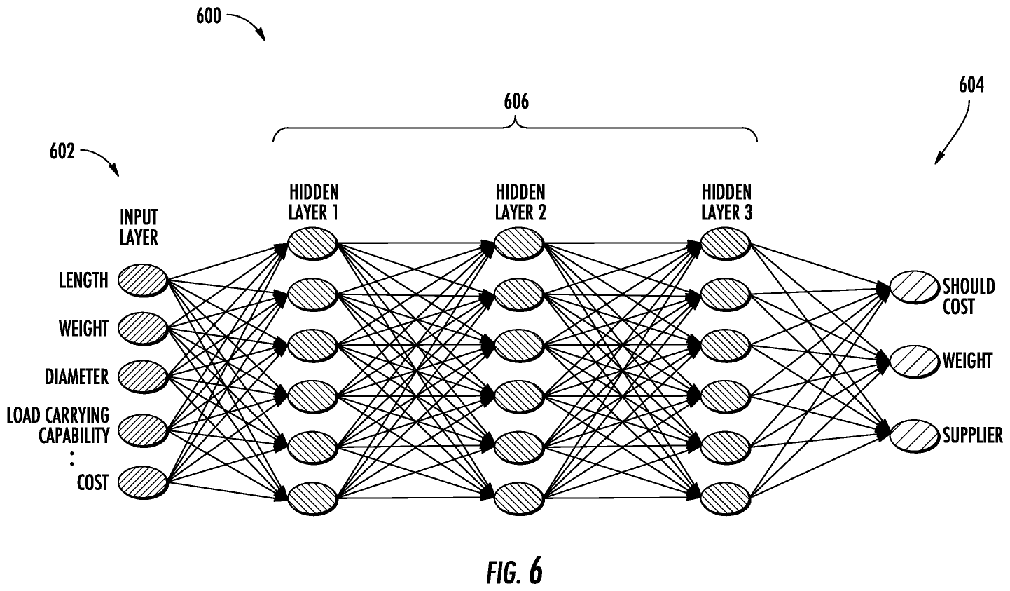

In some examples, this implementation of ML utilizes an artificial neural network (ANN), such as a multilayer perceptron (MLP) 600, as shown in FIG. 6. The MLP takes the clustered data as input, which may be considered training data for the MLP to utilize in order to predict the design for the structural part and thereby identify the supplier that is able to supply the design.

The MLP 600 may include multiple layers including an input layer 602, an output layer 604, and hidden layers 606 of nonlinearly-activated nodes. The nodes in a particular layer may be connected with a certain weight to each node in an adjacent layer. The MLP may be trained by changing the connection weights after a piece of data is processed, based on an amount of error in an output compared to an expected result.

In some examples, the input layer 602 may represent input features for the structural part. Each neuron in a hidden layer may transform values from previous layers with a weighted linear summation (e.g., w₁x₁+w₂x₂+ . . . wₘxₘ) followed by a nonlinear activation function (also referred to as a rectified linear unit function). An equation for the normal operation carried out considering a dataset of N groups of records by a jth neuron to compute the predicted output may be shown as:

Yj=+F(Σₙ₌₁^{N}XₙWₙᵢ+bᵢ) (Eq 1)

where x represents the input, b represents the bias of the node, w represents the weighting factor, and F represents the activation function. The output layer 604 may receive values from the adjacent hidden layer (shown as hidden layer 3) of the hidden layers 606 and transform the values to output values, which are shown in this example as cost (also referred to as “should cost”), weight, and supplier.

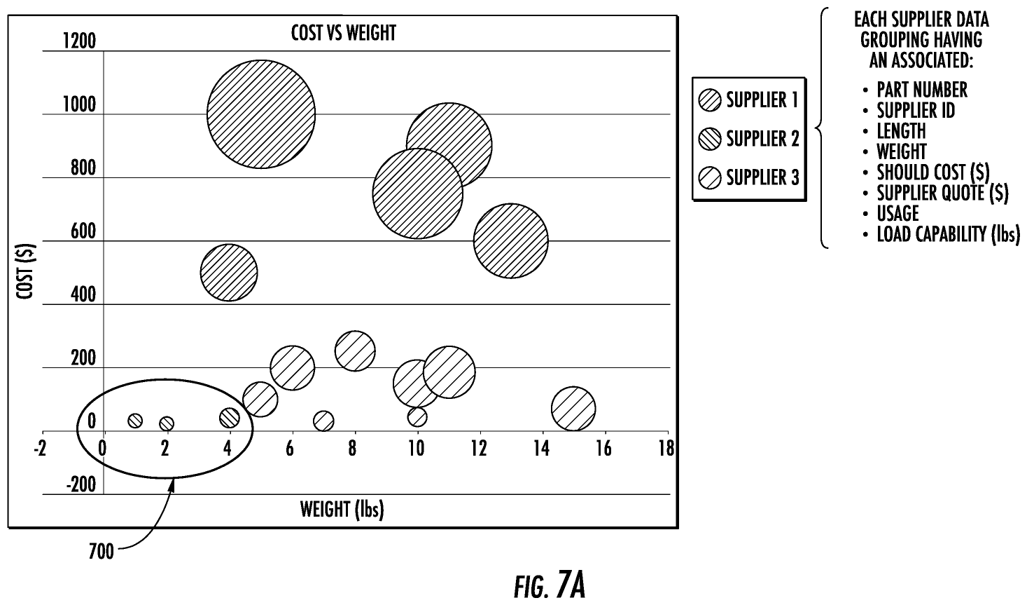

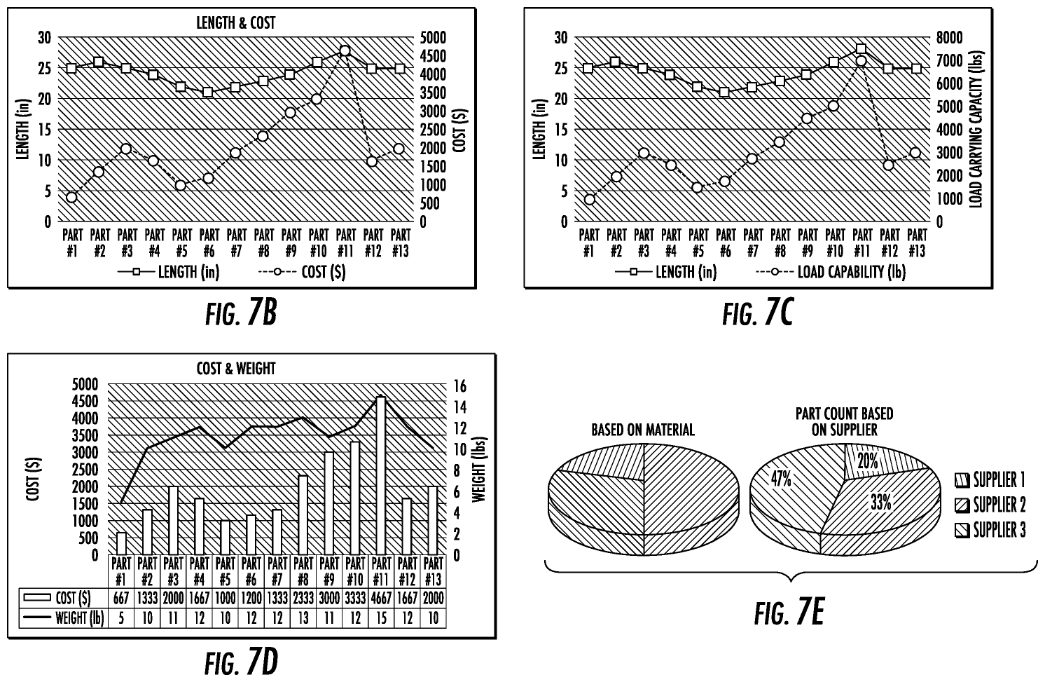

The output may be presented as appropriate to represent the identified supplier as well as other data regarding the design of the structural part. FIGS. 7A, 7B, 7C, 7D, and 7E respectively illustrate examples of outputs displaying cost/weight comparison, length/cost comparison, length/load capability comparison, cost/weight comparison, and structural part comparison based on material and supplier. In the example shown in FIG. 7A, the selected supplier 700 is chosen from a group of suppliers based on a cost versus weight comparison showing the selected supplier having structural part with the lowest cost and the lowest weight.

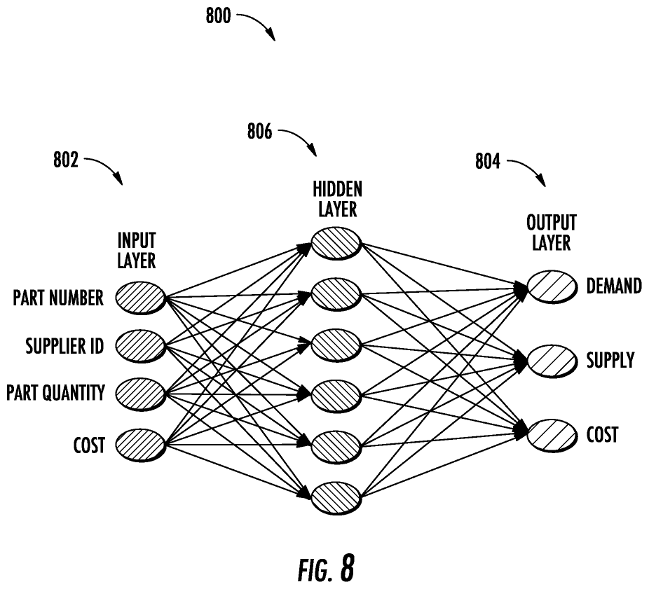

Supply chain forecasting may also be performed for the purpose of disruption avoidance regarding the supply of the structural part, which may be performed as an additional or separate implementation of MLP in the implementation of ML, as shown in FIG. 8. The MLP 800 of FIG. 8 may operate in a manner substantially similar to MLP 600—having an input layer 802 and an output layer 804 but with fewer hidden layers 806 in this example. For forecasting, the MLP may interact with multiple data sources including the manufacturing database to query information regarding historical data including cost, quantity, and supplier of the structural part. Forecasts of the future demand of the structural part may be based on the historical data and usage of the structural part. The MLP may help determine lead time for fulfilling the demand of the structural part and may predict the suppliers that are able to deliver the structural part (e.g., by priority ranking) with minimal disruption by satisfying the demand versus supply constraint.

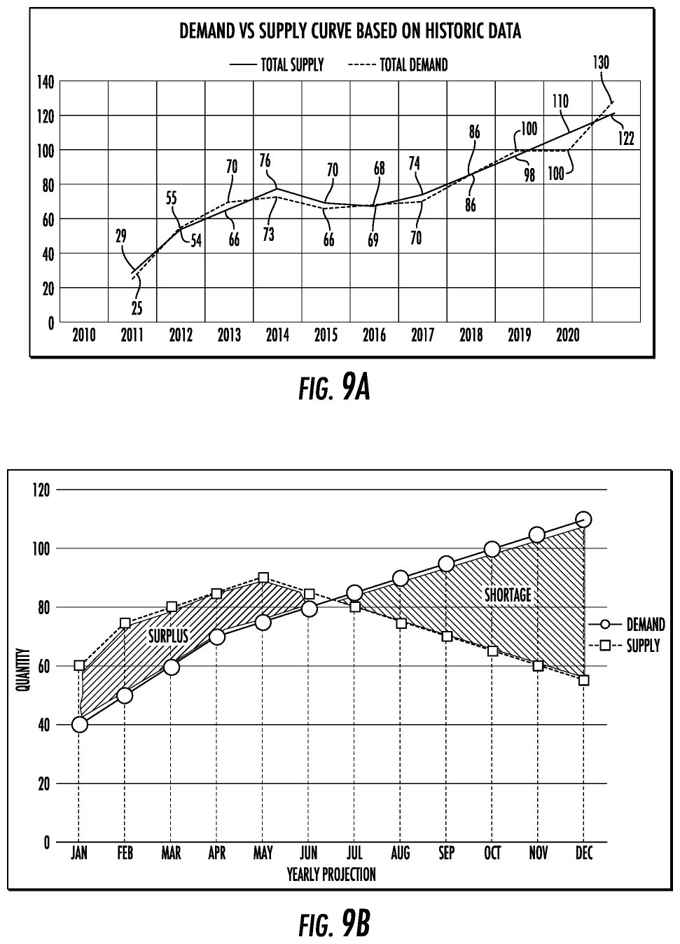

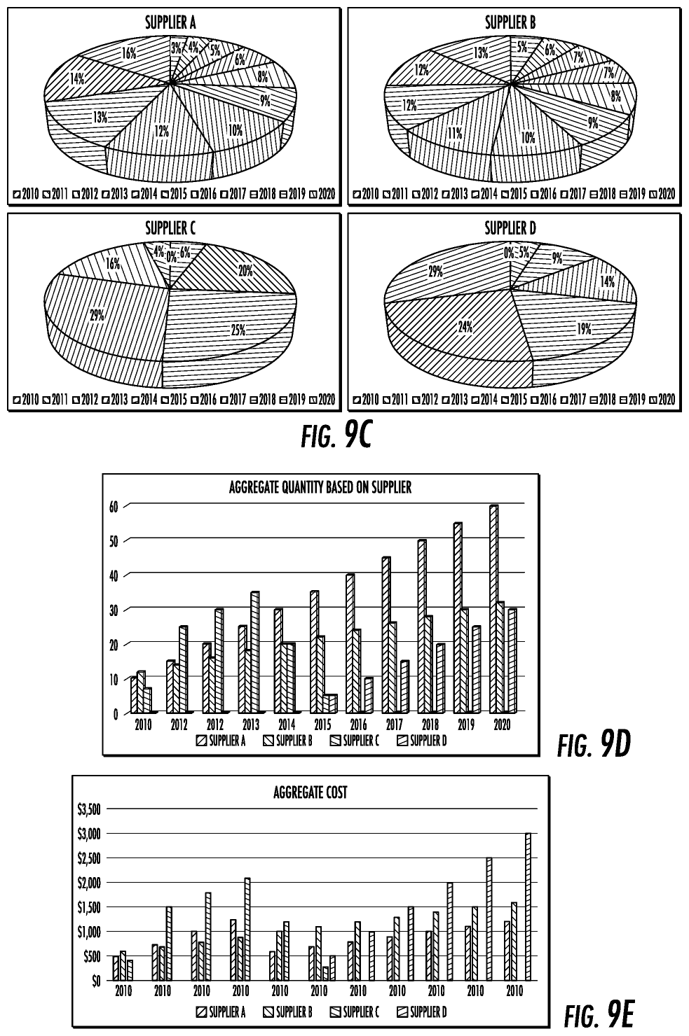

The forecasting may involve determining demand and supply trends based on the historical data and outputting a corresponding demand and supply curve, as shown in FIGS. 9A and 9B. As also shown in FIG. 9B, the output may also include a plot of future expectations for demand and supply based on the MLP, showing surplus and shortage as a yearly projection. Additional outputs based on the MLP for forecasting may include data regarding availability per supplier, aggregate quantity based on supplier, and aggregate cost, as shown respectively in FIGS. 9C, 9D, and 9E.

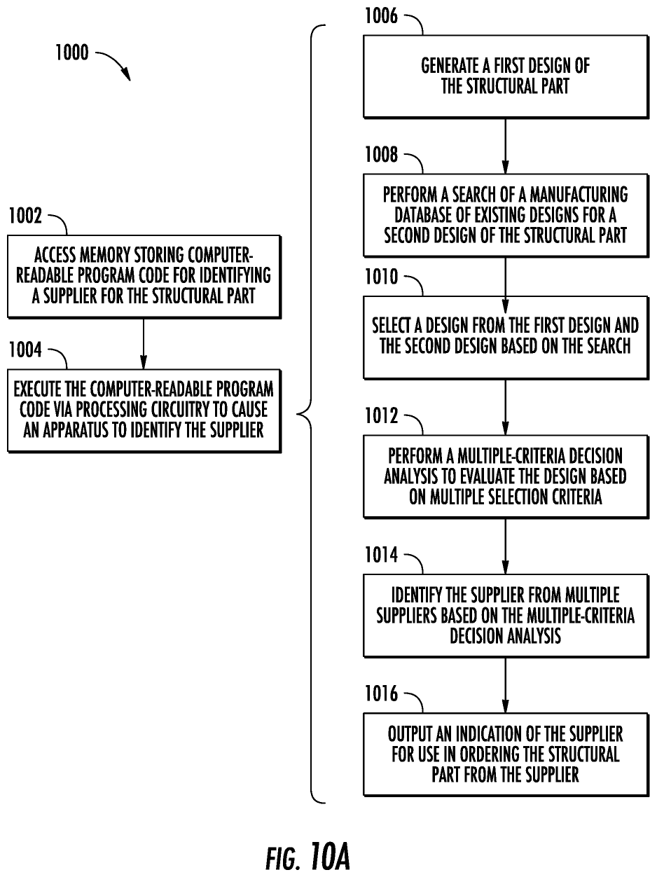

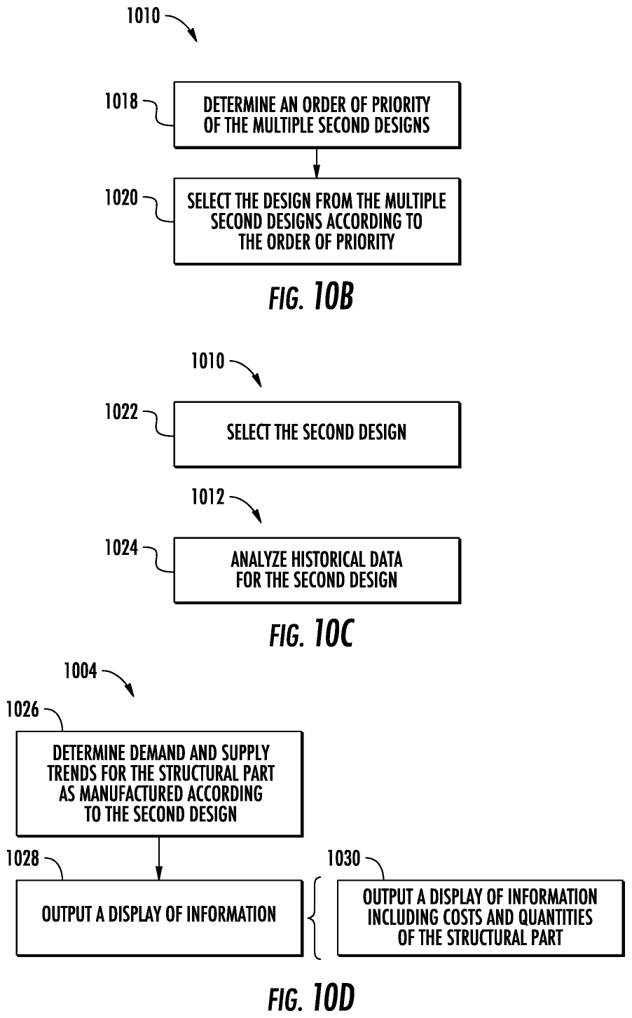

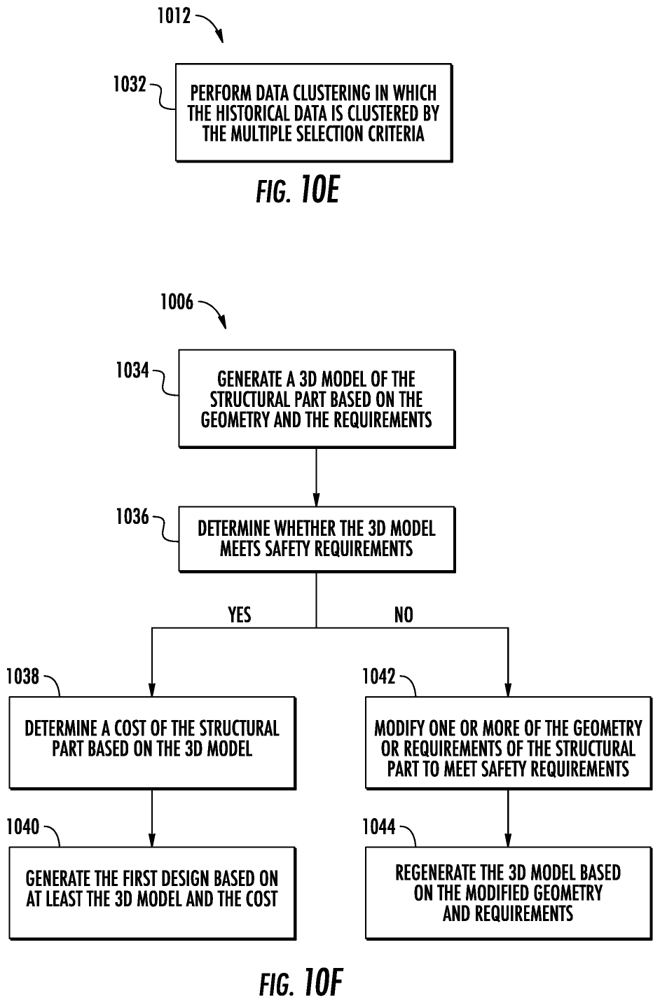

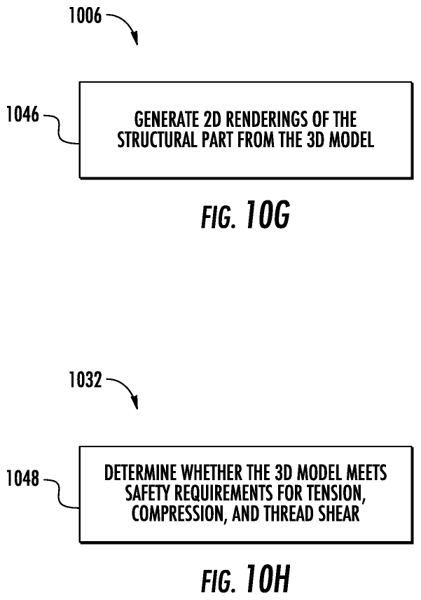

FIGS. 10A, 10B, 10C, 10D, 10E, 10F, 10G and 10H are flowcharts illustrating various steps in a method 1000 of managing a design lifecycle of a structural part, according to example implementations of the present disclosure. The method includes accessing memory 108 storing computer-readable program code 110 for identifying a supplier for a structural part, as shown at block 1002 in FIG. 10A. The method also includes executing the computer-readable program code, via processing circuitry 106 to cause an apparatus 102 to identify the supplier, as shown at block 1004.

As shown at block 1006, the apparatus caused to identify the supplier at block 1004 includes generating a first design 118 of the structural part, the first design describing a geometry of the structural part and requirements for attributes of the structural part including a rated capability, weight, and cost. Identifying the supplier also includes performing a search of a manufacturing database 104 of existing designs 114 for a second design 120 of the structural part based on search criteria including multiple ones of the geometry and the requirements, as shown at block 1008.

As shown at blocks 1010 and 1012, identifying the supplier at block 1004 includes selecting a design 122 from the first design 118 and the second design 120 based on the search, the second design selected when the second design matches the search criteria, and the first design selected when none of the existing designs 114 match the search criteria. Identifying the supplier also includes performing a multiple-criteria decision analysis to evaluate the design based on multiple selection criteria including the attributes of different units of the structural part as manufactured by multiple suppliers according to the design.

Ash shown at block 1014, identifying the supplier at block 1004 includes identifying the supplier from the multiple suppliers based on the multiple-criteria decision analysis. Identifying the supplier at block 1004 also includes outputting an indication of the supplier for use in ordering of the structural part from the supplier, as shown at block 1016.

In some examples, when multiple second designs 120 match the search criteria, selecting the design 122 at block 1010 includes determining an order of priority of the multiple second designs, and selecting the design from the multiple second designs according to the order of priority, as shown respectively at blocks 1018 and 1020 in FIG. 10B.

In some examples, when the structural part is a vehicle part, selecting the design 122 at block 1010 includes selecting the second design 120, as shown at block 1022 in FIG. 10C. And performing the multiple-criteria decision analysis at block 1012 includes analyzing historical data for the second design, including usage of the vehicle part as manufactured according to the second design, and across multiple vehicles, as shown at block 1024. As shown in FIG. 10D, in some of these examples the apparatus caused to identify the supplier at block 1004 further includes the apparatus at least determining demand and supply trends for the structural part as manufactured according to the second design, based on historical data for the second design, as shown at block 1026.

Also in some of these examples when the structural part is a vehicle part, identifying the supplier at block 1004 may also include outputting a display 124 of information including a demand and supply curve based on the demand and supply trends, the demand and supply curve informing at least one of a predicted demand or shortage in supply of the structural part, as shown at block 1028 in FIG. 10D. Outputting the display of information at block 1024 may include display of costs and quantities of the structural part from respective ones of the multiple suppliers, as shown at block 1030.

In some examples, as shown at block 1032 in FIG. 10E, performing the multiple-criteria decision analysis at block 1012 includes performing data clustering 502 in which the historical data is clustered by the multiple selection criteria based on parameters including one or more of a fixed number of clusters, a distance between a data point at a center of a cluster and other data points in the cluster, or a minimum number of data points in a cluster.

In some examples, generating the first design 118 at block 1006 comprises generating a three-dimensional (3D) model 202, 204 of the structural part based on the geometry and the requirements, and determining whether the 3D model meets safety requirements, as shown respectively at blocks 1034 and 1036 in FIG. 10F. And when the 3D model meets the safety requirements 302, generating the 3D model further comprises determining a cost of the structural part based on the 3D model, and generating the first design based on at least the 3D model and the cost, may be performed as shown respectively at blocks 1038 and 1040. When the 3D model does not meet the safety requirements, the method 1000 may further comprise modifying one or more of the geometry or requirements of the structural part to meet the safety requirements, as shown at block 1042, and regenerating the 3D model based on the geometry and the requirements as modified, as shown at block 1044.

In some examples, the structural part has geometric features including one or more tapers or holes, and generating the first design at block 1006 comprises generating two-dimensional (2D) renderings 202, 206 of the structural part from the 3D model, and based on dimensions of the geometric features, as shown at block 1046 in FIG. 10G.

In some examples, determining whether the 3D model meets safety requirements 302 at block 1032 comprises determining whether the 3D model meets safety requirements for tension, compression, and thread shear, as shown at block 1048 in FIG. 10H.

According to example implementations of the present disclosure, the system 100 and its subsystems including the apparatus 102 and the manufacturing database 104 may be implemented by various means. Means for implementing the system and its subsystems may include hardware, alone or under direction of one or more computer programs from a computer-readable storage medium. In some examples, one or more apparatuses may be configured to function as or otherwise implement the system and its subsystems shown and described herein. In examples involving more than one apparatus, the respective apparatuses may be connected to or otherwise in communication with one another in a number of different manners, such as directly or indirectly via a wired or wireless network or the like.

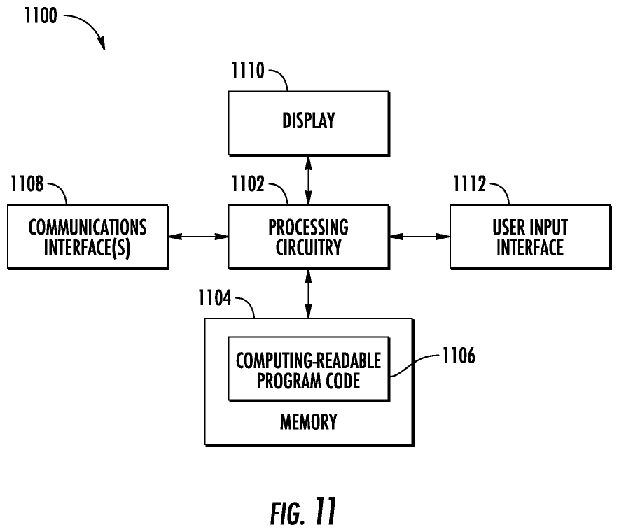

FIG. 11 illustrates an apparatus 1100 according to some example implementations of the present disclosure, such as the apparatus 102 of system 100 shown in FIG. 1. Generally, an apparatus of exemplary implementations of the present disclosure may comprise, include or be embodied in one or more fixed or portable electronic devices. Examples of suitable electronic devices include a smartphone, tablet computer, laptop computer, desktop computer, workstation computer, server computer or the like. The apparatus may include one or more of each of a number of components such as, for example, processing circuitry 1102 (e.g., processor unit) connected to a memory 1104 (e.g., storage device). The processing circuitry 1102 may correspond to processing circuitry 106 and memory 1104 may correspond to memory 108, as shown in apparatus 102 of system 100 in FIG. 1.

The processing circuitry 1102 may be composed of one or more processors alone or in combination with one or more memories. The processing circuitry is generally any piece of computer hardware that is capable of processing information such as, for example, data, computer programs and/or other suitable electronic information. The processing circuitry is composed of a collection of electronic circuits some of which may be packaged as an integrated circuit or multiple interconnected integrated circuits (an integrated circuit at times more commonly referred to as a “chip”). The processing circuitry may be configured to execute computer programs, which may be stored onboard the processing circuitry or otherwise stored in the memory 1104 (of the same or another apparatus).

The processing circuitry 1102 may be a number of processors, a multi-core processor or some other type of processor, depending on the particular implementation. Further, the processing circuitry may be implemented using a number of heterogeneous processor systems in which a main processor is present with one or more secondary processors on a single chip. As another illustrative example, the processing circuitry may be a symmetric multi-processor system containing multiple processors of the same type. In yet another example, the processing circuitry may be embodied as or otherwise include one or more ASICs, FPGAs or the like. Thus, although the processing circuitry may be capable of executing a computer program to perform one or more functions, the processing circuitry of various examples may be capable of performing one or more functions without the aid of a computer program. In either instance, the processing circuitry may be appropriately programmed to perform functions or operations according to example implementations of the present disclosure.

The memory 1104 is generally any piece of computer hardware that is capable of storing information such as, for example, data, computer programs (e.g., computer-readable program code 1106) and/or other suitable information either on a temporary basis and/or a permanent basis. The memory may include volatile and/or non-volatile memory, and may be fixed or removable. Examples of suitable memory include random access memory (RAM), read-only memory (ROM), a hard drive, a flash memory, a thumb drive, a removable computer diskette, an optical disk, a magnetic tape or some combination of the above. Optical disks may include compact disk-read only memory (CD-ROM), compact disk-read/write (CD-R/W), DVD or the like. In various instances, the memory may be referred to as a computer-readable storage medium. The computer-readable storage medium is a non-transitory device capable of storing information, and is distinguishable from computer-readable transmission media such as electronic transitory signals capable of carrying information from one location to another. Computer-readable medium as described herein may generally refer to a computer-readable storage medium or computer-readable transmission medium.

In addition to the memory 1104, the processing circuitry 1102 may also be connected to one or more interfaces for displaying, transmitting and/or receiving information. The interfaces may include a communications interface 1108 (e.g., communications unit) and/or one or more user interfaces. The communications interface may be configured to transmit and/or receive information, such as to and/or from other apparatus(es), network(s) or the like. The communications interface may be configured to transmit and/or receive information by physical (wired) and/or wireless communications links. Examples of suitable communication interfaces include a network interface controller (NIC), wireless NIC (WNIC) or the like.

The user interfaces may include a display 1110 and/or one or more user input interfaces 1112 (e.g., input/output unit). The display may be configured to present or otherwise display information to a user, suitable examples of which include a liquid crystal display (LCD), light-emitting diode display (LED), plasma display panel (PDP) or the like. The user input interfaces may be wired or wireless, and may be configured to receive information from a user into the apparatus, such as for processing, storage and/or display. Suitable examples of user input interfaces include a microphone, image or video capture device, keyboard or keypad, joystick, touch-sensitive surface (separate from or integrated into a touchscreen), biometric sensor or the like. The user interfaces may further include one or more interfaces for communicating with peripherals such as printers, scanners or the like.

As indicated above, program code instructions may be stored in memory, and executed by processing circuitry that is thereby programmed, to implement functions of the systems, subsystems, tools and their respective elements described herein. As will be appreciated, any suitable program code instructions may be loaded onto a computer or other programmable apparatus from a computer-readable storage medium to produce a particular machine, such that the particular machine becomes a means for implementing the functions specified herein. These program code instructions may also be stored in a computer-readable storage medium that can direct a computer, a processing circuitry or other programmable apparatus to function in a particular manner to thereby generate a particular machine or particular article of manufacture. The instructions stored in the computer-readable storage medium may produce an article of manufacture, where the article of manufacture becomes a means for implementing functions described herein. The program code instructions may be retrieved from a computer-readable storage medium and loaded into a computer, processing circuitry or other programmable apparatus to configure the computer, processing circuitry or other programmable apparatus to execute operations to be performed on or by the computer, processing circuitry or other programmable apparatus.

Retrieval, loading and execution of the program code instructions may be performed sequentially such that one instruction is retrieved, loaded and executed at a time. In some example implementations, retrieval, loading and/or execution may be performed in parallel such that multiple instructions are retrieved, loaded, and/or executed together. Execution of the program code instructions may produce a computer-implemented process such that the instructions executed by the computer, processing circuitry or other programmable apparatus provide operations for implementing functions described herein.

Execution of instructions by a processing circuitry, or storage of instructions in a computer-readable storage medium, supports combinations of operations for performing the specified functions. In this manner, an apparatus 1100 may include a processing circuitry 1102 and a computer-readable storage medium or memory 1104 coupled to the processing circuitry, where the processing circuitry is configured to execute computer-readable program code 1106 stored in the memory. It will also be understood that one or more functions, and combinations of functions, may be implemented by special purpose hardware-based computer systems and/or processing circuitry which perform the specified functions, or combinations of special purpose hardware and program code instructions.

Many modifications and other implementations of the disclosure set forth herein will come to mind to one skilled in the art to which the disclosure pertains having the benefit of the teachings presented in the foregoing description and the associated figures. Therefore, it is to be understood that the disclosure is not to be limited to the specific implementations disclosed and that modifications and other implementations are intended to be included within the scope of the appended claims. Moreover, although the foregoing description and the associated figures describe example implementations in the context of certain example combinations of elements and/or functions, it should be appreciated that different combinations of elements and/or functions may be provided by alternative implementations without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A method of managing a design lifecycle of a structural part, the method comprising:
accessing memory storing computer-readable program code for identifying a supplier for the structural part; and
executing the computer-readable program code, via processing circuitry, to cause an apparatus to identify the supplier, including the apparatus at least:
generating a first design of the structural part, the first design describing a geometry of the structural part and requirements for attributes of the structural part including a rated capability, weight, and cost;
performing a search of a manufacturing database of existing designs for a second design of the structural part based on search criteria including multiple ones of the geometry and the requirements;
selecting a design from the first design and the second design based on the search, the second design selected when the second design matches the search criteria, and the first design selected when none of the existing designs match the search criteria;
performing a multiple-criteria decision analysis to evaluate the design based on multiple selection criteria including the attributes of different units of the structural part as manufactured by multiple suppliers according to the design;
identifying the supplier from the multiple suppliers based on the multiple-criteria decision analysis; and
outputting an indication of the supplier for use in ordering of the structural part from the supplier.

2. The method of claim 1, wherein multiple second designs match the search criteria, and selecting the design includes determining an order of priority of the multiple second designs, and selecting the design from the multiple second designs according to the order of priority.

3. The method of claim 1, wherein the structural part is a vehicle part, selecting the design includes selecting the second design, and performing the multiple-criteria decision analysis includes analyzing historical data for the second design, including usage of the vehicle part as manufactured according to the second design, and across multiple vehicles.

4. The method of claim 3, wherein performing the multiple-criteria decision analysis includes performing data clustering in which the historical data is clustered by the multiple selection criteria based on parameters including one or more of a fixed number of clusters, a distance between a data point at a center of a cluster and other data points in the cluster, or a minimum number of data points in a cluster.

5. The method of claim 1, wherein the structural part is a vehicle part, selecting the design includes selecting the second design, and the apparatus caused to identify the supplier further includes the apparatus at least:
determining demand and supply trends for the structural part as manufactured according to the second design, based on historical data for the second design; and
outputting a display of information including a demand and supply curve based on the demand and supply trends, the demand and supply curve informing at least one of a predicted demand or shortage in supply of the structural part.

6. The method of claim 5, wherein outputting the display of information includes outputting the display of information further including costs and quantities of the structural part from respective ones of the multiple suppliers.

7. The method of claim 1, wherein generating the first design comprises:
generating a three-dimensional (3D) model of the structural part based on the geometry and the requirements;
determining whether the 3D model meets safety requirements; and when the 3D model meets the safety requirements,
determining a cost of the structural part based on the 3D model; and
generating the first design based on at least the 3D model and the cost.

8. The method of claim 7, wherein the structural part has geometric features including one or more tapers or holes, and generating the first design further comprises generating two-dimensional (2D) renderings of the structural part from the 3D model, and based on dimensions of the geometric features.

9. The method of claim 7, wherein determining whether the 3D model meets safety requirements comprises determining whether the 3D model meets safety requirements for tension, compression, and thread shear.

10. The method of claim 7, wherein when the 3D model does not meet the safety requirements, the method further comprises:
modifying one or more of the geometry or requirements of the structural part to meet the safety requirements; and
regenerating the 3D model based on the geometry and the requirements as modified.

11. An apparatus for managing a design lifecycle of a structural part, the apparatus comprising:
memory configured to store computer-readable program code for identifying a supplier for the structural part; and
processing circuitry configured to access the memory and execute the computer-readable program code to cause the apparatus to identify the supplier, including the apparatus caused to at least:
generate a first design of the structural part, the first design describing a geometry of the structural part and requirements for attributes of the structural part including a rated capability, weight, and cost;
perform a search of a manufacturing database of existing designs for a second design of the structural part based on search criteria including multiple ones of the geometry and the requirements;
select a design from the first design and the second design based on the search, the second design selected when the second design matches the search criteria, and the first design selected when none of the existing designs match the search criteria;
perform a multiple-criteria decision analysis to evaluate the design based on multiple selection criteria including the attributes of different units of the structural part as manufactured by multiple suppliers according to the design;
identify the supplier from the multiple suppliers based on the multiple-criteria decision analysis; and
output an indication of the supplier for use in ordering of the structural part from the supplier.

12. The apparatus of claim 1, wherein multiple second designs match the search criteria, and the apparatus caused to select the design includes the apparatus caused to determine an order of priority of the multiple second designs, and select the design from the multiple second designs according to the order of priority.

13. The apparatus of claim 1, wherein the structural part is a vehicle part, the apparatus caused to select the design includes the apparatus caused to select the second design, and the apparatus caused to perform the multiple-criteria decision analysis includes the apparatus caused to analyze historical data for the second design, including usage of the vehicle part as manufactured according to the second design, and across multiple vehicles.

14. The apparatus of claim 1, wherein the apparatus caused to perform the multiple-criteria decision analysis includes the apparatus caused to perform data clustering in which the historical data is clustered by the multiple selection criteria based on parameters including one or more of a fixed number of clusters, a distance between a data point at a center of a cluster and other data points in the cluster, or a minimum number of data points in a cluster.

15. The apparatus of claim 1, wherein the structural part is a vehicle part, the apparatus caused to select the design includes the apparatus caused to select the second design, and the apparatus caused to identify the supplier further includes the apparatus caused to at least:
determine demand and supply trends for the structural part as manufactured according to the second design, based on historical data for the second design; and
output a display of information including a demand and supply curve based on the demand and supply trends, the demand and supply curve informing at least one of a predicted demand or shortage in supply of the structural part.

16. The apparatus of claim 15, wherein the apparatus caused to output the display of information includes the apparatus caused to output the display of information further including costs and quantities of the structural part from respective ones of the multiple suppliers.

17. The apparatus of claim 1, wherein the apparatus caused to generate the first design further includes the apparatus caused to:
generate a three-dimensional (3D) model of the structural part based on the geometry and the requirements;
determine whether the 3D model meets safety requirements; and when the 3D model meets the safety requirements,
determine a cost of the structural part based on the 3D model; and
generate the first design based on at least the 3D model and the cost.

18. The apparatus of claim 17, wherein the structural part has geometric features including one or more tapers or holes, and the apparatus caused to generate the first design further comprises the apparatus caused to generate two-dimensional (2D) renderings of the structural part from the 3D model, and based on dimensions of the geometric features.

19. The apparatus of claim 17, wherein the apparatus caused to determine whether the 3D model meets safety requirements comprises the apparatus caused to determine whether the 3D model meets safety requirements for tension, compression, and thread shear.

20. The apparatus of claim 17, wherein when the 3D model does not meet the safety requirements, the apparatus further caused to:
modify one or more of the geometry or requirements of the structural part to meet the safety requirements; and
regenerate the 3D model based on the geometry and the requirements as modified.
